(19) United States
(12) Patent Application Publication
(10) Pub. No.: US 2012/0318351 A1
(43) Pub. Date: Dec. 20, 2012

(54) SOLAR CELL HAVING A SPECIAL BUSBAR SHAPE, SOLAR CELL ARRANGEMENT CONTAINING SAID SOLAR CELL, AND METHOD FOR PRODUCING THE SOLAR CELL

(75) Inventors: Andreas Pfennig, Leipzig (DE); Björn Faulwetter-Quandt, Leipzig (DE); Andreas Hubert, Leipzig (DE)

(73) Assignee: Q-CELLS SE, Bitterfeld-Wolfen / OT Thalheim (DE)

(21) Appl. No.: 13/582,016

(22) PCT Filed: Jan. 18, 2011
(86) PCT No.: PCT/DE11/75005

§ 371 Date: Aug. 30, 2012

(30) Foreign Application Priority Data
Mar. 2, 2010 (DE) 10 2010 002 521.6

(51) Int. Cl. H01L 31/0224; H01L 31/18

(52) U.S. Cl. 136/256; 438/98; 257/E31.124

(57) ABSTRACT

A solar cell includes a substrate, a semiconductor layer, a first busbar, and a second busbar. Along a connecting line, the first busbar has contact pads which have a maximum width b_{Imax}, perpendicular to the connecting line and between which there is respectively located on the connecting line a current collecting area which makes contact with the contact pads in a contact area, having on both sides of the connecting line two outer points whose spacing perpendicular to the connecting line defines a maximum width b_{Smax} of the current collecting area. Width b of the current collecting area and b_{Imax}<b_{Smax}, starting from one contact pad up to an adjacent contact pad, decreases down to a minimum width b_{Smin} between two inner points, and then increases up to the adjacent contact pad to a maximum width b_{Smax}′.

### CROSS REFERENCE TO RELATED APPLICATIONS

This application is a 371 National Stage filing of PCT International Application No. PCT/DE2011/075005, filed on Jan. 18, 2011, and published in German on Sep. 9, 2011 as WO 2011/107089 A2, which claims priority to German Patent Application No. DE 10 2010 002 521.6, filed on Mar. 2, 2010, the entire disclosures of which are incorporated herein by reference.

### FIELD OF THE INVENTION

The invention relates to a solar cell having a special busbar shape, a solar cell arrangement containing said solar cell, and a method for producing the solar cell.

### BACKGROUND OF THE INVENTION

Solar cells generally are composed of a layer structure that is formed in a plate-shaped semiconductor material, for example from monocrystalline or multicrystalline silicon. The semiconductor material forms the p-conducting base in this case. A thin n-conducting layer, the so-called emitter, is produced on the surface by indiffusion of phosphor. Contact with the base is usually made by means of an aluminum layer applied completely over the surface. Contact is made with the emitter via narrow fingers that are interconnected one under another by one or more so-called busbars. Since the metal fingers and busbars do not permit light to enter the areas of the cell where contact is made, whereas an excessively small number and width of fingers increases the series resistance, the fingers and busbars must be constructed such that electrical losses and shading losses are minimized.

In general, the busbars are designed in a strip shape, the busbars having a uniform width in the range of from 1.5 to 2 mm, as a rule. Solar cells are generally electrically interconnected by connecting their busbars with metallically conductive strips (also denoted as contact strips, soldering strips or interconnectors). As a rule, the contact strips are soldered onto the busbars. In practice, use is mostly made of a contact strip that is wider than the busbar of the solar cell. The reasons for this are, for example, inaccuracies in the positioning of a contact strip on a busbar, and instances of deformation of the contact strip (so-called sabers). If the width of the busbar is equal to the width of the contact strip, these effects lead to an additional shading, and therefore to a higher additional power loss.

Some variants are already known for the shape of the busbars (also denoted as busbar electrodes) on solar cells and their connection by means of contact strips.

Thus, JP 2006270043 A describes a solar cell module that is capable of preventing the peeling off of an internal lead wire of busbar electrodes on a solar cell element, while at the same time there is an increase in the electrical output power. To this end, the solar cell module has a solar cell element with busbar electrodes for removing the electrical power from their surfaces, and an internal lead wire that is electrically connected to the busbar electrodes over almost its entire length. The internal lead wire is structured so that its tip is shaped as the thinnest part.

JP 2008282990 A and WO 08/139,787 A1 describe a solar cell in the case of which a busbar electrode and a multiplicity of finger electrodes that extend from the busbar electrode are fitted on a first main surface of a semiconductor substrate. The busbar electrode contains a first conducting part in order to connect it to an interconnector, and a bypass part that is connected to the first conducting part, of which a part is not connected to the interconnector.

DE 10 2007 062 689 A1 describes designs of contact and current collecting electrodes for solar cells that have thin current collecting fingers at relatively small spacing arranged in parallel fashion on a front side of the solar cell, and form rows composed of individual connecting points for holding soldered on contact strips made from metal such as, for example, copper, aluminum, in order to remove electrical current from the solar cell. In this case, the rows of the individual connecting points are formed substantially on a straight line at right angles to the current collecting fingers, and several parallel fingers are respectively brought together on both sides in the region of connecting points, and the connections formed can be connected to the metal contact strip.

JP 2006266262 A (WO 07/122,897A) describes a solar cell with an interconnector, a solar cell module and a method for the production of a solar cell module. A busbar electrode and a collector electrode are provided on a light-receiving surface, and an interconnector is connected to the top surface of the busbar electrode. With this solar cell, the busbar electrode is wider than the interconnector, and an area in the width direction of the top surface of the busbar electrode where the interconnector is not connected has a part without soldering flux.

US 2009/277491 A describes a solar cell that contains a semiconductor substrate that has a first main surface. Provided on the first main surface are a busbar electrode and a multiplicity of linear finger electrodes that extend from the busbar electrode. The busbar electrode contains a first connecting part that is to be connected to an interconnector, and a second, non-connecting part that is not connected to an interconnector. The first connecting part and the second non-connecting part are arranged in an alternating fashion.

Against this background, it was the object of the invention to provide a solar cell in the case of which effects such as positioning errors of a contact strip and saber effects do not lead to a power loss.

According to this invention, this object is achieved by a solar cell having the features of the appropriate independent patent claim, by the method for producing this solar cell of the appropriate independent claim, and by a solar cell arrangement comprising said solar cell. Preferred embodiments of the solar cell according to the invention are set forth in appropriate dependent patent claims. Preferred embodiments of the method according to the invention correspond to preferred embodiments of the solar cell according to the invention and vice versa, even if this is not explicitly stated herein.

### SUMMARY OF THE INVENTION

The subject matter of the invention is therefore a solar cell, comprising a substrate, a semiconductor layer, a first busbar on a first surface of the semiconductor layer, and a second busbar on a second surface of the semiconductor layer, wherein, along a connecting line, the first busbar has contact pads which have a maximum width b_{Imax} perpendicular to the connecting line and between which there is respectively located on the connecting line a current collecting area which makes contact with the contact pads in a contact area, the contact area having on both sides of the connecting line two outer points P1 and P2 whose spacing perpendicular to the connecting line defines a maximum width b_{Smax} of the current collecting area, wherein b_{Smax}<b_{Smax}, and the width b of the current collecting area, starting from one contact pad up to an adjacent contact pad, first decreases down to a minimum width b_{Smin} between two inner points P3 and P4, and then increases again up to the adjacent contact pad to a maximum width b_{Smax}′.

In a preferred embodiment of the solar cell, a ratio between b_{Imax} and b_{Smax} is in the range of from 1.1 to 15, with particular preference in the range of from 1.3 to 10.

It is, moreover, preferred when a ratio between b_{Smax} and b_{Smin} is in the range of from 1.05 to 20, with particular preference in the range of from 1.1 to 15.

In a further preferred embodiment of the solar cell, a ratio between b_{Imax} and a spacing d between two contact pads is in the range of from 2 to 30, in particular in the range of from 5 to 20.

The contact pads can have different geometric shapes. Round and angular shapes are possible. Preferred round shapes are circles and ellipses. Preferred angular shapes are quadrilaterals or hexagons. According to the invention, it is preferred for the contact pads to be designed as circles.

The contact pads are equipped at least partially with an electrically conductive material.

The contact pads can preferably have cutouts. This means in general that only a part of a contact pad has an electrically conductive material. However, it is also possible for only some of the contact pads to have cutouts. By way of example, the cutout can be a circular surface such that the electrically conductive material is located in an annulus arranged around this circular surface. Other geometric shapes for the cutout are, however, possible, including a grid structure.

In a preferred embodiment of the solar cell according to the invention, an angle α between a first straight line through the point P1 and the point P3, and a second straight line through the point P2 and the point P4 is in the range of from 3 to 50°, the points P1 and P3 and the points P2 and P4 respectively being arranged on the same side of the connecting line with particular preference in the range of from 5 to 45°, and with very particular preference in the range of from 8 to 40°.

The first and the second straight lines can be imaginary straight lines, since any desired geometry is possible for the profile of the current collecting area between the contact pads. Thus, the area between points P1 and P3, as also the area between points P2 and P4 can be linear or curved. The area between point P1 and point P3 and the area between point P2 and point P4 are preferably substantially linear. Substantially linear means, above all, that the magnitude of a gradient of a straight line at the point P3 and at the point P4 is preferably somewhat smaller than at the point P1 or P2, so that, starting from P1, the width of the current collecting area preferably initially decreases linearly to where a curved area adjoins in the area around the point P3, after which the width of the current collecting area once again increases linearly up to the next contact pad.

It is preferred that an angle β between a first tangent to the contact pad at the point P1, and a second tangent to the contact pad at the point P2 is in the range of between 50 and 150°, especially preferably in the range between 70 and 130°.

It is preferred according to the invention that the contact pads and the current collecting areas of the solar cell contain an electrically conductive paste. The solar cell can be obtained by printing the conductive paste, that is to say by metallization, by means of screen printing. As an alternative or in addition thereto, it is possible to provide layers in a different way, for example by electroplating.

In the solar cell according to the invention, the substrate is generally a transparent disk, for example made from glass or polycarbonate, preferably from glass.

In general, apart from the substrate, the semiconductor layer and the busbar, the solar cell of the invention also comprises further layers, for example a single layer or multilayer film, an antireflection layer (for example made from silicon nitride) and/or a further protective film (for example made from ethylene vinyl acetate polymer).

Given a size of 100 to 200 mm×100 to 200 mm along a connecting line, a solar cell according to the invention generally has 8 to 15, preferably 10 to 13, contact pads. The contact pads in this case preferably have a size with dimensions in the range of from 1 to 2 mm and are, for example, circular areas with a diameter of between 1 and 2 mm, preferably of from 1.3 to 1.7 mm, in particular 1.4 to 1.6 mm.

The subject of the invention is, furthermore, a method for producing a solar cell as described above, comprising the step that, on a solar cell comprising a substrate, a semiconductor layer, a first busbar on a first surface of the semiconductor layer, and a second busbar on a second surface of the semiconductor layer, the first busbar is applied to the first surface of the semiconductor layer such that, along a connecting line, the first busbar has contact pads which have a maximum width b_{Imax} perpendicular to the connecting line and between which there is respectively located on the connecting line a current collecting area which makes contact with the contact pads in a contact area, the contact area having on both sides of the connecting line two outer points P1 and P2 whose spacing perpendicular to the connecting line defines a maximum width b_{Smax} of the current collecting area, wherein b_{Imax}<b_{Smax}, and the width b of the current collecting area, starting from one contact pad up to an adjacent contact pad, first decreases down to a minimum width b_{Smin} between two inner points P3 and P4, and then increases again up to the adjacent contact pad to a maximum width b_{Smax}′.

The subject of the invention is, furthermore, a solar cell arrangement in which at least two of the above described solar cells are interconnected in an electrically conducting fashion by connecting a first busbar on a first solar cell by means of a contact strip to a second busbar on an adjacent solar cell.

In a preferred embodiment of the invention, a ratio between the maximum width b_{Imax} of the contact pads and a width b_{KB} of the contact strip is in the range of between 0.5 and 2.0, more preferably in the range of between 0.6 and 1.5.

The solar cell arrangement can, in particular, be a linear arrangement of solar cells in the shape of a string, or a two-dimensional arrangement for the purpose of a solar module.

A soldering method is generally applied to connect the first busbar on the first solar cell to the second busbar on the adjacent solar cell with the aid of a contact strip. The soldering methods that can be used according to the invention include, in particular, infrared soldering, hot air soldering, flame soldering, induction soldering, stamp soldering (contact soldering with a hot soldering tip, a hot soldering stirrup or similar) or laser soldering.

The invention has the advantage that solar cells can be interconnected in a more efficient way to form solar cell arrangements such as strings or modules. Shading losses and, in general, a power mismatch can be minimized in this way.

Further details of the invention emerge from the following description of non-limiting exemplary embodiments for the solar cell, the solar cell arrangement and the method according to the invention. Reference is made in this case to FIGS. 1 to 3.

### BRIEF DESCRIPTION OF THE DRAWINGS

FIG. 1 shows a plan view of a section from a busbar of a solar cell according to the invention, where two contact pads are interconnected by means of a current collecting area along a connecting line.

FIG. 2 shows a side view of a solar cell arrangement according to the invention in which three solar cells are interconnected electrically in series.

FIG. 3 shows a plan view of a solar cell according to the invention having three busbars in the case of which contact pads are respectively interconnected by means of current collecting areas along a connecting line.

### DETAILED DESCRIPTION OF THE DRAWINGS

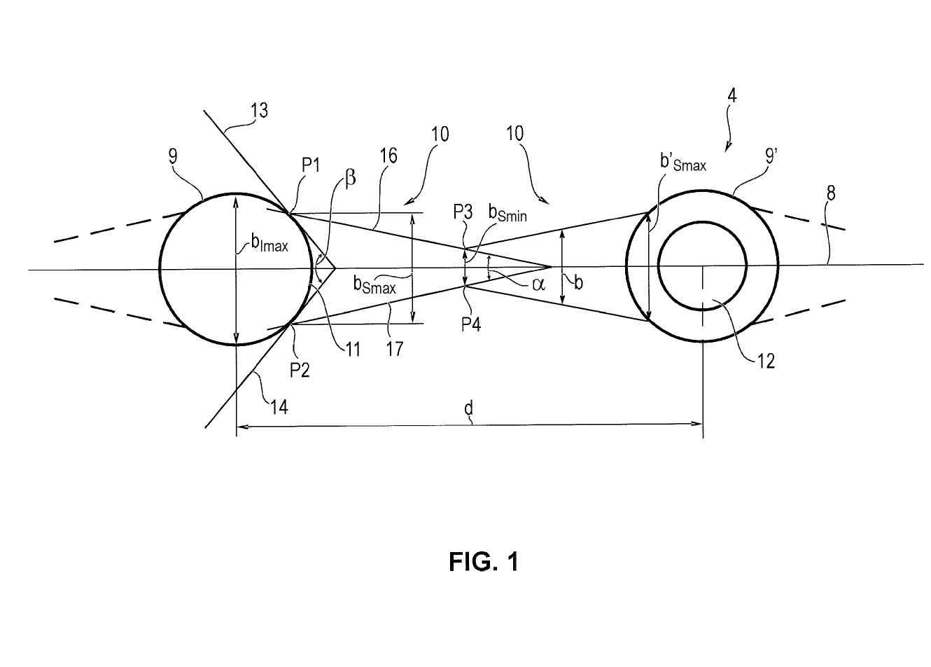

FIG. 1 shows a plan view of a section from a first busbar 4 of a solar cell according to the invention in which two contact pads 9, 9′ are interconnected by means of a current collecting area 10 along a connecting line 8.

The first busbar 4 has, in particular along the connecting line 8, contact pads 9, 9′ with a maximum width b_{Smax} perpendicular to the connecting line 8. Located between the contact pads 9, 9′ on the connecting line 8 are, respectively, a current collecting area 10 that makes contact with the contact pads 9, 9′ in a contact area 11, the contact area 11 having on both sides of the connecting line 8 two external points P1 and P2, whose spacing perpendicular to the connecting line 8 defines a maximum width b_{Smax} of the current collecting area (10), wherein b_{Imax}<b_{Smax}. The width b of the current collecting area 10, starting from one contact pad 9 up to an adjacent contact pad 9′, first decreases down to a minimum width b_{Smin} between two inner points P3 and P4, and then increases again up to the adjacent contact pad 9′ to a maximum width b_{Smax}′.

In the case of the embodiment shown in FIG. 1, a ratio between b_{Imax} and b_{Smax} is in the range of from 1.3 to 10, a ratio between b_{Smax} and b_{Smin} is in the range of from 1.1 to 15, and a ratio between b_{Smax} and a distance d between two contact pads 9, 9′ is in the range of from 5 to 20.

In FIG. 1, the left-hand contact pad 9 is configured as a circle, in particular as a filled circle, while the right-hand contact pad 9′ is a circle with a circular cutout 12, that is to say is designed as an annulus.

In the embodiment shown in FIG. 1, an angle α between a first straight line 16 through the point P1 and the point P3, and a second straight line 17 through the point P2 and the point P4 is in the range of from 8 to 40°, the points P1 and P3 and the points P2 and P4 respectively being arranged on the same side of the connecting line 8.

The first straight line 16 and the second straight line 17 illustrate here the linear decrease in the width of the current collecting area 10 starting from the external points P1 and P2. In the area of the points P3 and P4, the straight lines flatten out such that the current collecting area 10 is wider here than would be expected on the basis of the linear profile of the straight lines.

In the case of the busbar of FIG. 1, an angle β between a first tangent 13 to the contact pad 9 at the point P1, and a second tangent 14 to the contact pad 9 at the point P2 is in the range of between 70 and 130°.

In the embodiment of FIG. 1, the contact pads 9 and 9′ and the current collecting areas 10 contain an electrically conductive paste that has been applied by printing the conductive paste by means of screen printing.

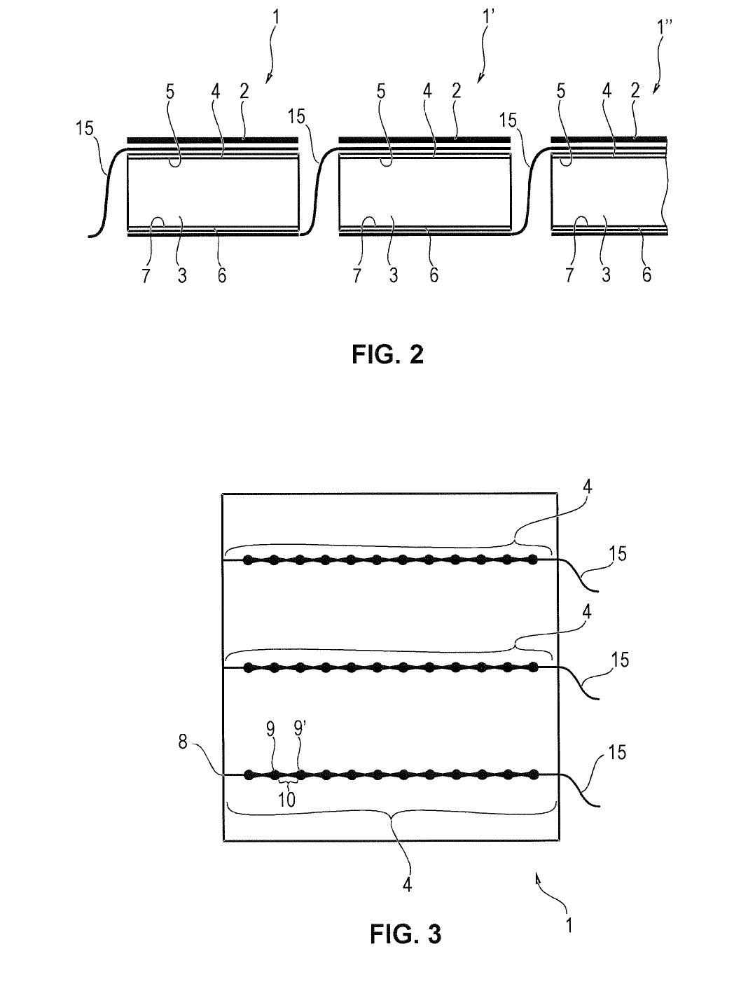

FIG. 2 shows a side view of a solar cell arrangement in which three solar cells 1, 1′ and 1″ are interconnected electrically in series. Each solar cell 1, 1′ and 1″ comprises a substrate 2, here a glass plate, a semiconductor layer 3, a first busbar 4 on a first surface 5 of the semiconductor layer 3, and a second busbar 6 on a second surface 7 of the semiconductor layer 3. A contact strip 15 respectively connects two adjacent solar cells. In FIG. 2, to this end a contact strip 15 connects the second busbar 6 of the solar cell 1 to the first busbar 4 of the solar cell 1′. Moreover, a contact strip 15 connects the second busbar 6 of the solar cell 1′ to the first busbar 4 of the solar cell 1″. A series connection of the solar cells is achieved in this way.

FIG. 3 shows a plan view of an solar cell 1 according to the invention having three first busbars 4, in the case of which 12 contact pads 9, 9′, etc. are respectively inter-connected by means of current collecting areas 10 along a connecting line 8. The contact strips 15 are shown, which connect the solar cell 1 via the three first busbars 4 to an adjacent solar cell (not shown here).

1. A solar cell comprising:
a substrate, a semiconductor layer, a first busbar on a first surface of the semiconductor layer, and a second busbar on a second surface of the semiconductor layer,
wherein, along a connecting line, the first busbar has contact pads which have a maximum width b_{Imax} perpendicular to the connecting line and between which there is respectively located on the connecting line a current collecting area which makes contact with the contact pads in a contact area,
the contact area having on both sides of the connecting line a first outer point and a second outer point whose spacing perpendicular to the connecting line defines a maximum width b_{Smax} of the current collecting area, wherein b_{Imax}<b_{Smax}, and
a width b of the current collecting area, starting from one contact pad up to an adjacent contact pad first decreases down to a minimum width b_{Smin} between a first inner point and a second inner point, and then increases again up to the adjacent contact pad to a maximum width b_{Smax}′.

2. The solar cell as claimed in claim 1, wherein a ratio between b_{Imax} and b_{Smax} is in a range from 1.1 to 15.

3. The solar cell as claimed in claim 1, wherein a ratio between b_{Smax} and b_{Smin} is in a range from 1.05 to 20.

4. The solar cell as claimed in claim 1, wherein a ratio between b_{Imax} and a spacing d between two contact pads is in a range from 2 to 30.

5. The solar cell as claimed in claim 1, wherein the contact pads are designed as circles.

6. The solar cell as claimed in claim 1, wherein the contact pads have cutouts.

7. The solar cell as claimed in claim 1, wherein an angle α between a first straight line through the first inner point and the first outer point, and a second straight line through the second outer point and the second inner point is in a range from 3 to 50°, the first inner point and the first outer point, and the second inner point and the second outer point, respectively being arranged on a same side of the connecting line.

8. The solar cell as claimed in claim 1, wherein an angle β between a first tangent to the contact pad at the first outer point, and a second tangent to the contact pad at the second outer point is in the range of between 50 and 150°.

9. The solar cell as claimed in claim 1, wherein the contact pads and the current collecting areas contain an electrically conductive paste.

10. The solar cell as claimed in claim 9, wherein the solar cell can be obtained by printing the conductive paste by screen printing.

11. A method for producing a solar cell as claimed in claim 1, wherein, on a solar cell comprising a substrate, a semiconductor layer, a first busbar on a first surface of the semiconductor layer, and a second busbar on a second surface of the semiconductor layer, the method comprising:
the first busbar being applied to the first surface of the semiconductor layer such that along a connecting line, the first busbar has contact pads which have a maximum width b_{Imax} perpendicular to the connecting line and between which there is respectively located on the connecting line a current collecting area which makes contact with the contact pads in a contact area, the contact area having on both sides of the connecting line the first outer point and the second outer point whose spacing perpendicular to the connecting line defines a maximum width b_{Smax} of the current collecting area, wherein b_{Imax}<b_{Smax}, and the width b of the current collecting area, starting from one contact pad up to an adjacent contact pad, first decreases down to a minimum width b_{Smin} between the first inner point and the second inner point, and then increases again up to the adjacent contact pad to a maximum width b_{Smax}′.

12. A solar cell arrangement in which at least two solar cells are interconnected in an electrically conducting fashion by connecting a first busbar on a first solar cell by a contact strip to a second busbar on an adjacent solar cell, wherein a solar cell as claimed in claim 1 is used as the first solar cell.

13. The solar cell arrangement as claimed in claim 12, wherein a ratio between the maximum width b_{Imax} of the contact pads and a width b_{KB} of the contact strip is in a range between 0.5 and 2.0.
